(19) United States
(12) Patent Application Publication
(10) Pub. No.: US 2010/0263908 A1
(43) Pub. Date: Oct. 21, 2010

(54) METHOD FOR FABRICATION OF CONDUCTIVE FILM USING CONDUCTIVE FRAME AND CONDUCTIVE FILM

(76) Inventors: Hyun-Jung LEE, Seoul (KR); Hee-Suk KIM, Seoul (KR); Sun-Young NOH, Seoul (KR); Sun-Na Hwang, Seoul (KR); Soon-Ho LIM, Seoul (KR); Min PARK, Seoul (KR); Jun-Kyung KIM, Seoul (KR)

Correspondence Address: OSTROLENK FABER GERB & SOFFEN, 1180 AVENUE OF THE AMERICAS, NEW YORK, NY, 100368403, US

(21) Appl. No.: 12/575,699

(22) Filed: Oct. 8, 2009

(30) Foreign Application Priority Data
Apr. 15, 2009 (KR) 10-2009-0032915

(51) Int. Cl. H01B 5/00; B05D 1/36; C23C 16/00; B05D 1/02; B29C 47/00; C25D 13/00; C25D 5/34

(52) U.S. Cl. 174/126.1; 427/407.1; 427/255.28; 427/294; 264/465; 204/486; 205/188; 977/742; 977/750; 977/752

(57) ABSTRACT

Disclosed are a method for fabricating a conductive film, and a conductive film fabricated by the same. The method comprises: forming a mixed solution consisting of at least one of a metallic precursor and a conductive polymer; spraying atomized droplets of the mixed solution on a surface of a substrate so as to form conductive frames; and coupling carbon nanotubes to the conductive frames so as to enhance electric conductivity. Accordingly, the conductive film can have enhanced electric conductivity, and can be easily fabricated.

### CROSS-REFERENCE TO RELATED APPLICATIONS

This application claims priority to Korean Application No. 10-2009-0032915, filed on Apr. 15, 2009, which is herein incorporated by reference in its entirety.

### BACKGROUND OF THE INVENTION

1. Field of the Invention

The present invention relates to a method for fabrication of a conductive film having electric conductivity and light transmittance, and a conductive film fabricated by the same.

2. Background of the Invention

A conductive film is a kind of functional optical film, and is being widely applied to home devices, industrial devices, office devices, etc.

Nowadays, a transparent conductive film having a light transmission characteristic is being widely applied to devices implementing low transparency and low resistance, such as solar cells and each kind of displays (PDP, LCD and OLED). As the transparent conductive film, indium tin oxide (ITO) has been generally used.

However, the ITO has the following disadvantages.

Firstly, the ITO is expensive, and has a weak endurance against even a small external impact or stress.

Secondly, the ITO has a weak mechanical stability when being bent or folded.

Thirdly, an electric characteristic of the ITO is varied by thermal deformation due to a difference between a coefficient of thermal expansion of the ITO and that of a substrate.

In order to solve these problems, has been proposed a simple method for fabricating a conductive film having high electric conductivity and high light transmittance.

### SUMMARY OF THE INVENTION

Therefore, an object of the present invention is to provide a method for fabricating a conductive film capable of fabricating a conductive film in a different is manner from the conventional art, and a conductive film fabricated by the same.

Another object of the present invention is to provide a conductive film having an enhanced endurance.

To achieve these and other advantages and in accordance with the purpose of the present invention, as embodied and broadly described herein, there is provided a method for fabricating a conductive film, comprising: forming a mixed solution consisting of at least one of a metallic precursor and a conductive polymer; spraying atomized droplets of the mixed solution on a surface of a substrate so as to form conductive frames; and coupling carbon nanotubes to the conductive frames so as to enhance electric conductivity.

According to another aspect of the present invention, the metallic precursor may be formed of at least one of cobalt, nickel, copper, silver, gold, iron, cadmium, rubidium, tin and indium. The conductive polymer may be formed of at least one of polypyrrol, polyaniline and polythiophene. A solvent may include at least one of dimethylformamide (DMF), N-methyl-2-pyrrolidone (NMP), ethyl alcohol, water and chlorobenzene.

According to another aspect of the present invention, the coupling step may include dispersing carbon nanotubes in a solvent; and depositing the carbon nanotubes on a substrate by using the dispersion solution. As the depositing method, may be used one of spin coating, chemical vapor deposition (CVD), electrochemical deposition, electrophoretic deposition, spray coating, dip-coating, vacuum filtration, airbrushing, stamping and doctor blade.

According to another aspect of the present invention, the method for fabricating a conductive film further comprises preprocessing the carbon nanotubes by at least one of a cutting step and a chemical reaction step with acid.

According to another embodiment of the present invention, there is provided a method for fabricating a conductive film, comprising: preparing a mixed solution consisting of at least one of a metallic precursor and a conductive polymer; forming net-shaped conductive frames on a substrate by electro-spinning the mixed solution; and coupling carbon nanotubes to the conductive frames such that the carbon nanotubes fill gaps between strips of the conductive frames.

To achieve these and other advantages and in accordance with the purpose of the present invention, as embodied and broadly described herein, there is also provided a conductive film, comprising: a transparent substrate; and an electrode layer formed on one surface of the transparent substrate.

The electrode layer may include conductive frames and carbon nanotubes.

The conductive frames may be formed so that a plurality of strips thereof can be twisted to each other in a net shape.

The carbon nanotubes may be coupled to the conductive frames such that gaps between the strips become conductive.

The conductive frames may include at least one of conductive polymers and metal wires.

The substrate may be formed of at least one of glass, quartz, and synthetic resin.

The carbon nanotubes may be formed of at least one of single-walled carbon nanotubes, double-walled carbon nanotubes, and multi-walled carbon nanotubes.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1A is a conceptual view of a conductive film according to one embodiment of the present invention;

FIG. 1B is a sectional view taken along line ′I-I′ in FIG. 1A;

FIG. 2 is a flowchart showing a method for fabricating a conductive film according to one embodiment of the present invention;

FIG. 3 is a flowchart showing a method for fabricating a conductive film according to another embodiment of the present invention; and

FIGS. 4A and 4B are enlarged views of the conductive film of FIG. 1A, which were photographed by a scanning electron microscope (SEM), respectively.

### DETAILED DESCRIPTION OF THE INVENTION

Description will now be given in detail of the present invention, with reference to the accompanying drawings.

Hereinafter, a method for fabricating a conductive film, and a conductive film fabricated by the same according to the present invention will be explained in more detail with reference to the attached drawings.

The same or similar reference numerals will be given to the same or similar parts in different embodiments, and their detailed explanation will be omitted. The singular expression used in the specification of the present invention may include the meaning of plurality unless otherwise defined.

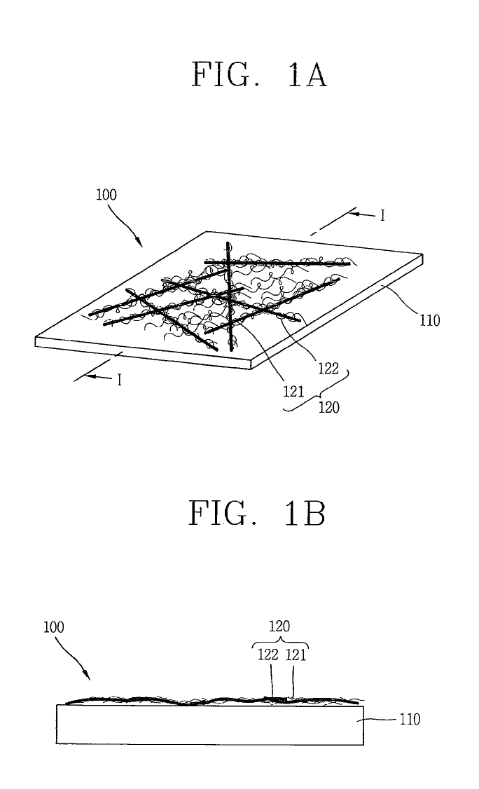

FIG. 1A is a conceptual view of a conductive film 100 according to one embodiment of the present invention, and FIG. 1B is a sectional view taken along line ′I-I′ in FIG. 1A.

Referring to FIGS. 1A and 1B, the conductive film 100 comprises a transparent substrate 110, and an electrode layer 120.

The substrate 110 may be formed of at least one of glass, quartz, and synthetic resin. And, the substrate 110 may constitute a base of the conductive film 100, and may be formed in a net shape.

The electrode layer 120 is formed on one surface of the substrate 110. The electrode layer 120 includes conductive frames 121, and carbon nanotubes (CNTs) 122.

The conductive frames 121 may be formed so that a plurality of strips thereof can be twisted to each other in a net shape. As the plurality of strips of the conductive frames 121 are electrically connected to each other to form a network, empty spaces are formed among the plurality of strips. As a result, the conductive film 100 has enhanced light transmittance.

The conductive frames 121 may include at least one of conductive polymers and metal wires.

The conductive polymer may be formed of at least one of polypyrrol, polyaniline and polythiophene. The metal wire may be formed of at least one of cobalt, nickel, copper, silver, gold, iron, cadmium, rubidium, tin and indium.

The carbon nanotubes 122 are coupled to the conductive frames 121. In order to implement high electric conductivity of the conductive frames 121, the carbon nanotubes 122 are formed on the conductive frames 121.

As the conductive frames 121 and the carbon nanotubes 122 are coupled to each other by an electrostatic attractive force, the conductive film 100 has high electric conductivity.

The carbon nanotubes 121 may be formed of at least one of single-walled carbon nanotubes, double-walled carbon nanotubes, and multi-walled carbon nanotubes. The multi-walled carbon nanotubes may include thin multi-walled carbon nanotubes.

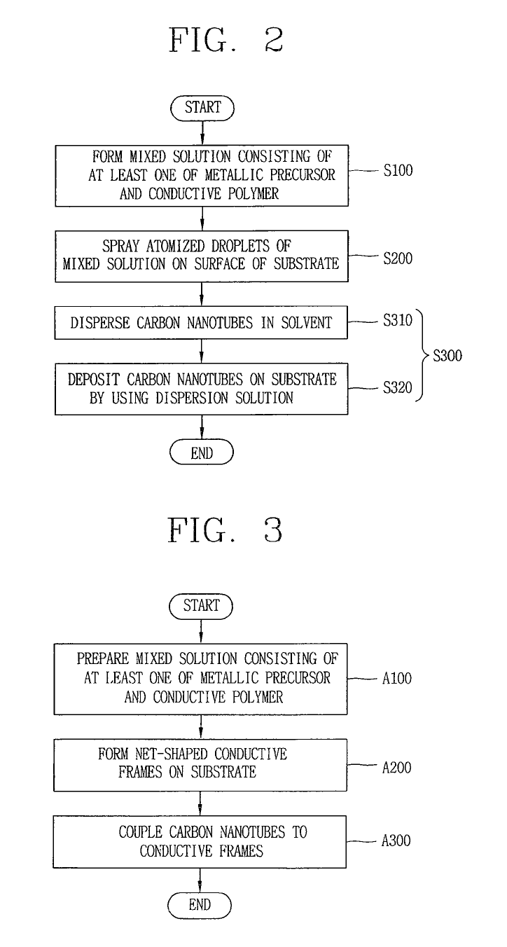

Hereinafter, will be explained a method for fabricating the conductive film 100 shown in FIGS. 1A and 1B. FIG. 2 is a flowchart showing a method for fabricating a conductive film according to one embodiment of the present invention.

Firstly, formed is a mixed solution consisting of at least one of a metallic precursor and a conductive polymer (S100).

The metallic precursor may be formed of at least one of cobalt, nickel, copper, silver, gold, iron, cadmium, rubidium, tin and indium. The conductive polymer may be formed of at least one of polypyrrol, polyaniline and polythiophene.

The step of forming a mixed solution (S100) will be explained by taking an example.

Firstly, about 15% by weight of AgNO₃ solution is formed. The AgNO₃ solution may be formed by mixing about 0.3 g of AgNO₃ and 1.7 ml of acetonitrile with each other, and then by sputtering the mixture at a room temperature for 30 minutes.

Next, 10% by weight of poly vinyl alcohol (PVA) aqueous solution is formed. The poly vinyl alcohol (PVA) aqueous solution may be formed by mixing about 0.5 g of poly vinyl alcohol (PVA) with 4.5 ml of distilled water, and then by stirring the mixture at a temperature of 80° for 3 hours.

The AgNO₃ solution and the poly vinyl alcohol (PVA) aqueous solution are mixed with each other, and are stirred at a room temperature for one hour, thereby forming a mixed solution.

Next, atomized droplets of the mixed solution are sprayed on a surface of a substrate so as to form conductive frames (S200).

The dispersion may be performed by an electro-spinning method. The substrate may be formed of at least one of glass, quartz, and synthetic resin.

The spraying step (S200) will be explained by taking an example.

Firstly, the mixed solution is electro-spinned on a substrate formed of quartz. A distance between the substrate and an opening of a spray device for the mixed solution may be about 15 cm, a voltage may be 25 kV, and time taken to perform an electro-spinning process may be 30 minutes. The mixture solution may be introduced into the opening of the spray device by using nitrogen having a constant pressure of about 0.03 MPa.

Finally, the substrate is thermally processed at a temperature of 800° C. for five hours under an atmosphere of argon or air. As a result, conductive frames, e.g., silver wires are formed on the substrate in the shape of a net. Here, a heating rate may be about 2.3° C./min.

In the forming step (S100) and the spraying step (S200), transmittance of the substrate consisting of the conductive frames may be controlled by controlling a concentration, an electro-spinning time, etc. of the mixed solution.

Next, carbon nanotubes are coupled to the conductive frames so as to is enhance electric conductivity (S300).

The coupling step (S300) may include a dispersing step (S310) and a depositing step (S320).

In the dispersing step (S310), the carbon nanotubes are dispersed in a solvent. The solvent may include at least one of dimethylformamide (DMF), N-methyl-2-pyrrolidone (NMP), ethyl alcohol, water and chlorobenzene.

The carbon nanotubes may be preprocessed so as to have an enhanced affinity with a solvent. The preprocessing may be performed by at least one of a cutting step and a chemical reaction step with acid.

The preprocessing step and the dispersing step (S310) will be explained by taking an example.

400 mg of carbon nanotubes are stirred in a mixed solution of sulfuric acid and nitric acid having a volume ratio of 3:1 for one hour, thereby being cut. Then, the cut carbon nanotubes are diluted by using distilled water, thereby forming carbon nanotubes suspension. Next, the carbon nanotubes suspension is filtered by a polytetrafluoroethylene (PTFE) membrane, and is dried by a freeze dryer. As a result, the carbon nanotubes are cut in a state that carboxyl groups thereof have been exposed out.

0.03% by weight of the cut carbon nanotubes are put in a dimethylformamide (DMF) solvent, and then are dispersed by using a sonicator for to two hours.

In the depositing step (S320), the carbon nanotubes are deposited on the substrate by using the dispersion solution. In the depositing step (S320), electric conductivity is enhanced by selectively absorbing the carbon nanotubes to the conductive frames.

As the depositing method, may be used one of spin coating, chemical vapor deposition (CVD), electrochemical deposition, electrophoretic deposition, spray coating, dip-coating, vacuum filtration, airbrushing, stamping and doctor blade.

The depositing step (S320) will be explained by taking an example.

The carbon nanotube dispersion solution undergoes a vacuum filtration process, thereby forming carbon nanotube buckypaper. On the carbon nanotube buckypaper, a substrate coated with silver wires is stamped. As a result, the carbon nantotubes are coupled with the silver wires.

FIG. 3 is a flowchart showing a method for fabricating a conductive film according to another embodiment of the present invention.

Referring to FIG. 3, the method for fabricating a conductive film comprises a mixed solution forming step (A100) for forming a mixed solution consisting of at least one of a metallic precursor and a conductive polymer; a conductive frame forming step (A200) for forming net-shaped conductive frames on the substrate by electro-spinning the mixed solution; and a coupling step (A300); and coupling carbon nanotubes to the conductive frames such that the carbon nanotubes fill gaps between strips of the conductive frames.

The carbon nanotubes may undergo a physical cutting process or an oxidation process so as to have an enhanced dispersion efficiency. The carbon nanotubes may undergo the physical cutting process by having supersonic wave applied thereto. By the oxidation process, the carbon nanotubes may be oxidized in a state that carboxyl groups thereof have been exposed out.

In order to enhance electric conductivity of a conductive film implemented as carbon nanotubes form electrode layers, the amount of the carbon nanotubes is has to be increased. However, in this case, the conductive film may have decreased transmittance. To solve this problem, in the present invention, the conductive film is implemented as the carbon nanotubes are coupled to the conductive frames. Accordingly, a more effective conductive path is formed with a smaller amount of the carbon nanotubes.

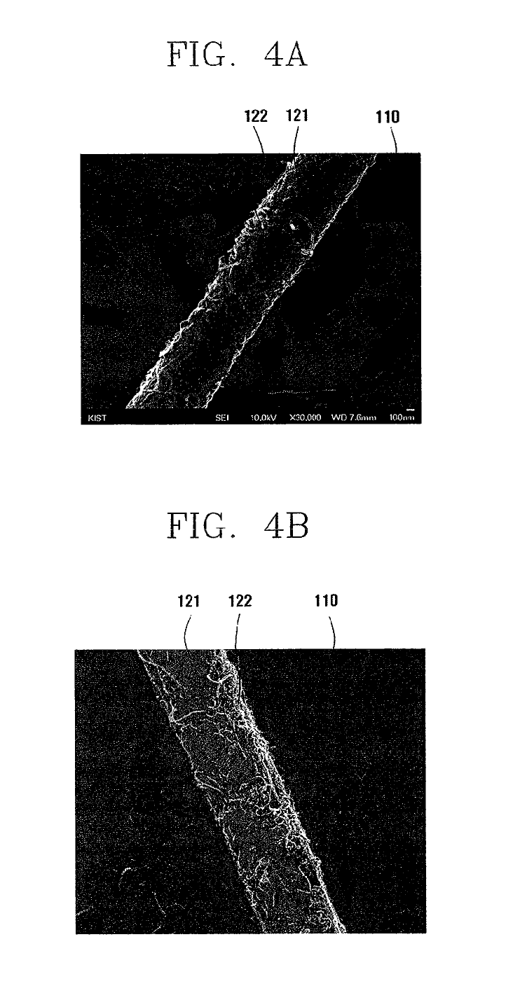

FIGS. 4A and 4B are enlarged views of the conductive film 100 of FIG. 1A, which were photographed by a scanning electron microscope (SEM), respectively. Referring to FIGS. 4A and 4B, the conductive frames 121 and the carbon nanotubes are coupled to each other. And, the conductive frames 121 are formed to have a size similar to or larger than a size of the carbon nanotubes 122. Accordingly, the conductive frames 121 constitute frames of a conductive path formed on the electrode layer 120 (refer to FIG. 1A). The carbon nanotubes 122 are extending to empty spaces on the substrate 110 from the conductive frames 121. As a result, the conductive path is completed by the carbon nanotubes.

The following table shows a surface resistance and transmittance of the conductive film, respectively. The surface resistance was measured by a four-point probe method, and the transmittance was measured by a UV-Vis-NIR spectrophotometer.

| MWNT deposition | Surface resistance | |
|---|---|---|
| (times) | (kΩ/sq) | Transmittance (%) |
| 5 | 2682 | 93 |
| 10 | 36 | 87 |

Referring to the table, when the number of frequencies that the multiwalled-nanotubes (MWNT) are deposited is increased by two times, the surface resistance is decreased by about 80 times whereas the transmittance is decreased by about 6%. Through the above table, it can be seen that the conductive film formed of the conductive frames and the carbon nanotubes has transmittance scarcely influenced by deposition frequencies, and enhanced electric conductivity.

The method for fabricating a conductive film and the conductive film by the same according to the present invention have the following advantages.

Firstly, as the carbon nanotubes are coupled to the conductive frames, the conductive film can have enhanced electric conductivity.

Secondly, as the conductive frames are formed in a net shape, the conductive film can have enhanced transmittance.

Thirdly, as atomized droplets of the mixed solution are sprayed on the surface of the substrate, the conductive film can be fabricated with low costs.

The foregoing embodiments and advantages are merely exemplary and are not to be construed as limiting the present disclosure. The present teachings can be readily applied to other types of apparatuses. This description is intended to be illustrative, and not to limit the scope of the claims. Many alternatives, modifications, and variations will be apparent to those skilled in the art. The features, structures, methods, and other characteristics of the exemplary embodiments described herein may be combined in various ways to obtain additional and/or alternative exemplary embodiments.

As the present features may be embodied in several forms without departing from the characteristics thereof, it should also be understood that the above-described embodiments are not limited by any of the details of the foregoing description, unless otherwise specified, but rather should be construed broadly within its scope as defined in the appended claims, and therefore all changes and modifications that fall within the metes and bounds of the claims, or equivalents of such metes and bounds are therefore intended to be embraced by the appended claims.

What is claimed is:

1. A method for fabricating a conductive film, comprising:
forming a mixed solution consisting of at least one of a metallic precursor and a conductive polymer;
spraying atomized droplets of the mixed solution on a surface of a substrate so as to form conductive frames; and
coupling carbon nanotubes to the conductive frames so as to enhance electric conductivity.

2. The method of claim 1, wherein the metallic precursor is formed of at least one of cobalt, nickel, copper, silver, gold, iron, cadmium, rubidium, tin and indium.

3. The method of claim 1, wherein the conductive polymer is formed of at least one of polypyrrol, polyaniline and polythiophene.

4. The method of claim 1, wherein the coupling step comprises:
dispersing carbon nanotubes in a solvent; and
depositing the carbon nanotubes on a substrate by using the dispersion solution.

5. The method of claim 4, wherein the depositing method comprises one of spin coating, chemical vapor deposition (CVD), electrochemical deposition, electrophoretic deposition, spray coating, dip-coating, vacuum filtration, airbrushing, stamping and doctor blade.

6. The method of claim 1, further comprising preprocessing the carbon nanotubes by at least one of a cutting step and a chemical reaction step with acid.

7. The method of claim 1, wherein the solvent comprises at least one of dimethylformamide (DMF), N-methyl-2-pyrrolidone (NMP), ethyl alcohol, water and chlorobenzene.

8. A conductive film, comprising:
a transparent substrate; and
an electrode layer formed on one surface of the transparent substrate,
wherein the electrode layer comprises:
conductive frames configured such that a plurality of strips thereof are twisted to each other in a net shape; and
carbon nanotubes coupled to the conductive frames such that gaps between the strips become conductive.

9. The conductive film of claim 8, wherein the conductive frames comprise at least one of conductive polymers and metal wires.

10. The conductive film of claim 8, wherein the substrate is formed of at least one of glass, quartz, and synthetic resin.

11. The conductive film of claim 8, wherein the carbon nanotubes are formed of at least one of single-walled carbon nanotubes, double-walled carbon nanotubes, and multi-walled carbon nanotubes.

12. A method for fabricating a conductive film, comprising:
preparing a mixed solution consisting of at least one of a metallic precursor and a conductive polymer;
forming net-shaped conductive frames on a substrate by electro-spinning the mixed solution; and
coupling carbon nanotubes to the conductive frames such that the carbon nanotubes fill gaps between strips of the conductive frames.
